(19) United States
(12) Patent Application Publication
(10) Pub. No.: US 2012/0189128 A1
(43) Pub. Date: Jul. 26, 2012

(54) ELECTROACOUSTIC DEVICE, IN PARTICULAR FOR A CONCERT HALL

(75) Inventors: Julien Maillard, Saint Martin D'Heres (FR); Isabelle Schmich, Grenoble (FR); Christophe Rougier, Grenoble (FR)

(73) Assignee: CENTRE SCIENTIFIQUE ET TECHNIQUE DU BATIMENT, Champs Sur Marne (FR)

(21) Appl. No.: 13/263,295

(22) PCT Filed: Apr. 9, 2010
(86) PCT No.: PCT/EP2010/054686

§ 371 Date: Feb. 7, 2012

(30) Foreign Application Priority Data
Apr. 9, 2009 (FR) 0952353
May 27, 2009 (FR) 0902557

(51) Int. Cl. H03G 11/00

(52) U.S. Cl. 381/55

(57) ABSTRACT

The device according to exemplary embodiments of the invention includes means for compensating the effects of temperature for cells that are used to obtain reverberation effects in an auditorium. This avoids the disagreeable effects of the “Larsen” effect, for example. The invention may be applicable to a public address system in a concert hall.

The present invention relates to an electroacoustic device for use in particular in a concert hall, the electroacoustic device including at least a soundwave pickup member and a soundwave playback member connected together by at least one processor circuit.

A major application (use) of this type of devices lies particularly in improving listening conditions in concert halls. What is often desired is provision of reverberation, for example to give a sensation of a large space, as is greatly appreciated for symphony concerts, even though the hall may be of small dimensions.

In this kind of application, it is possible to make use of the teaching given in patent document FR 2 449 318.

The device described in that patent document may be confronted by problems of instability. The device picks up sound signals in order to play them back subsequently after a certain delay, and since there is coupling between the sound pickup members (microphones) and the playback members (loudspeakers), instabilities of the Larsen effect type may arise. They therefore need to be combated.

One cause of instability is temperature fluctuation since that varies the speed of sound. The initial adjustments run the risk of no longer being adapted to the changes in sound paths that are modified by temperature fluctuations. No measures are described in the above-mentioned patent document for taking account of temperature changes. It is therefore not possible with that prior art device to perfect its settings since they are falsified by such temperature fluctuations.

The object of the invention is to mitigate the harmful effects of temperature changes.

To do this, such an electroacoustic device is remarkable in that it includes compensation members that provide compensation for temperature changes.

In a first embodiment of the invention, an electroacoustic device for use in particular in a concert hall comprises a plurality of acoustic cells, each formed by at least one soundwave pickup member and at least one soundwave playback member (HP1, HP2, HP3, HP4), and including an echo-canceller circuit (30) formed by a filter involving a multitude of coefficients. It is remarkable in that a thermometer member is provided for measuring ambient temperature in order to act on the multitude of coefficients as a function of ambient temperature.

In a preferred, second embodiment of the invention, said echo-canceller circuit receives replicas coming from a plurality of sound pickup members included in said device. These replicas are combined by matrixing. Thus, sound playback by the loudspeaker takes account of all of the sound space of the hall. This matrixing complicates initial adjustments, and once more it is necessary to avoid such sound quality being degraded by the temperature fluctuations that will degrade the various initial adjustment parameters. The measure recommended by the invention serves to remedy the temperature problem even when all of the signals from the various microphones are processed by matrixing.

The following description accompanied by the accompanying drawings, both given by way of non-limiting example, make it easily understood how the invention can be implemented.

In the drawings:

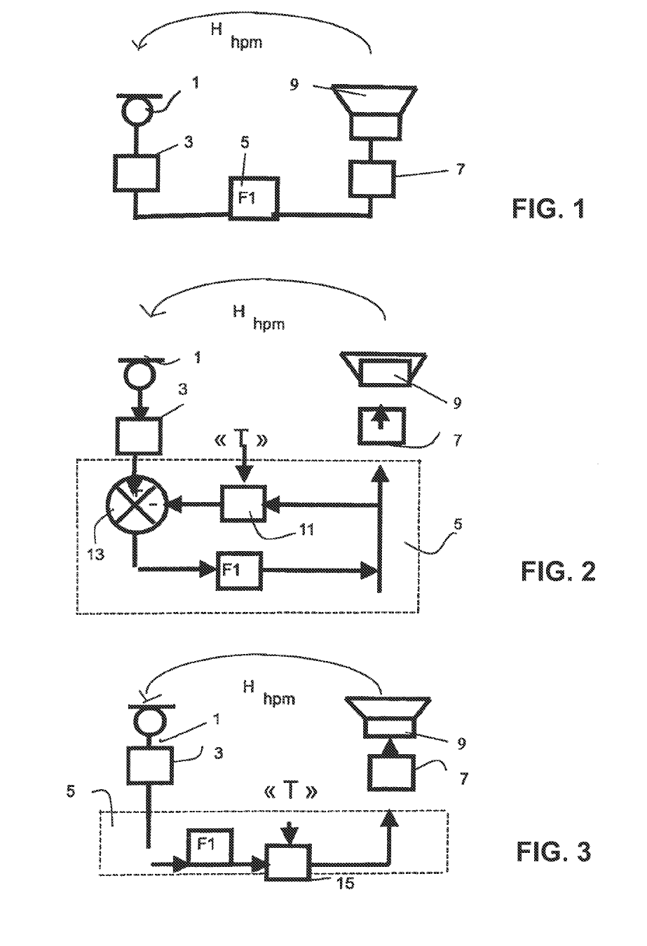

FIG. 1 shows a first type of device of the prior art;

FIG. 2 shows a second type of device to which the measures of the invention have been applied;

FIG. 3 shows a cell of the first type to which the measures of the invention have been applied;

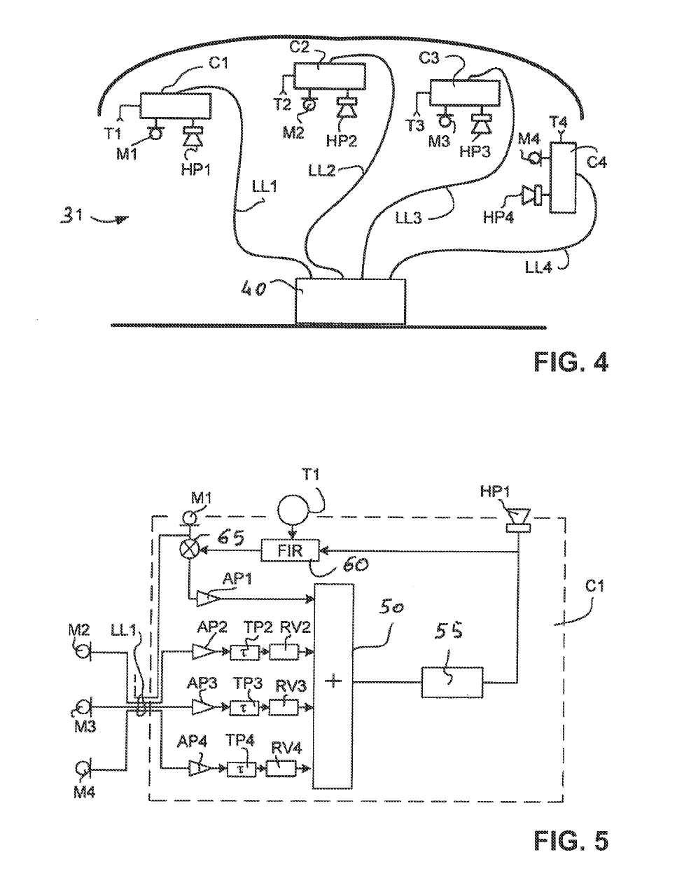

FIG. 4 shows a device in accordance with the invention involving signal matrixing; and

FIG. 5 shows an acoustic cell suitable for forming part of a device of the invention.

In the figures, common elements are given the same references.

Firstly the problem is summarized. The parameters for stabilizing such electroacoustic devices correspond to a given environment surrounding the cell and to a given acoustic path between a loudspeaker and a microphone. In particular, these parameters are determined at a given temperature. Unfortunately, when the temperature varies, the speed of sound varies in the same direction, since those two magnitudes are associated by the relationship c=\sqrt{γRT}. When the temperature varies, the sound reflections reaching the microphone are thus no longer the same, since they propagate at a different speed and therefore arrive at different instants. The acoustic path Hₕₚₘ is also modified since the properties of the soundwave propagation medium are modified. As a result, the parameters for stabilizing the device no longer correspond to the environment to which they were determined.

Furthermore, the experimental use of such microphone-loudspeaker decoupling techniques reveal drift in the stability of a cell as a function of the value of the ambient temperature surrounding the cell.

The invention relates to a technique for correcting stability as a function of temperature, for each stabilization principle of a cell. The stability parameters of the device are determined during adjustment at an initial temperature T₀. The invention consists in taking the parameters as determined at a temperature T₀ and adjusting them as a function of temperature variations.

It is then recalled that an electroacoustic system for active control of the reverberation of a hall is composed of:
one or more microphones for picking up a sound field;
one or more signal processor units acting on the signal(s) coming from the microphone(s); and
one or more loudspeakers for playing back the previously-processed audio signal(s).

In-line systems are characterized by the microphone(s) being positioned close to the source in order to pick up mainly the direct field coming from the source. The loudspeakers are distributed in the hall in order to provide uniform sound coverage. The processing of the signals is then made up essentially of artificial reverberation.

Regenerative systems are characterized by the microphone(s) being positioned in the reverberant sound field of the hall. Each microphone is connected to one or more loudspeakers via a low-value gain.

The hybrid systems that are in use are based on picking up the reverberant sound field by the microphone(s) and applying signal processing thereto that is based on artificial reverberation.

An electroacoustic system for active control of reverberation may be constituted by a plurality of “cells”, each comprising an assembly of a microphone plus a signal processor unit plus a loudspeaker. When the microphone and the loudspeaker are very close together, there is a risk of the cell becoming unstable (the Larsen effect). A system to which the invention may be applied is a system of the regenerative type constituted by a plurality of independent cells. The microphone and the loudspeaker of a cell are very close together, being about 1 meter (m) apart.

FIG. 1 shows a prior-art, first example of an electroacoustic system for active reverberation control. It is thus composed of a microphone 1, a preamplifier 3, a processor circuit 5, an amplifier 7, and a loudspeaker 9. To control the stability of this cell, a directional microphone is used with its axis of minimum sensitivity pointing towards the directivity axis of the loudspeaker (as mentioned in the above-mentioned patent document), together with a gain and a selective filtering (filter F1) performed by the processor circuit 5.

FIG. 2 shows another example of a cell of an electroacoustic system for active reverberation control. Here the processor circuit 5 includes an echo-canceller filter 11. The echo-canceller 11 is used when low-selectivity directivity of the microphone greatly decreases the acoustic decoupling of the cell.

In order to ensure sufficient decoupling of the cell, the echo-canceller filter 11 needs to estimate as exactly as possible the acoustic transfer function (or acoustic path) between the loudspeaker and the microphone (Hₕₚₘ). Echoes coming solely from the loudspeaker (and not from the sound field present in the hall) are then canceled by taking the difference between the signal coming from the preamplifier and the signal coming from the filter F1, by means of a subtracter device 13.

The echo-canceller 11 corresponds to the acoustic path Hₕₚₘ, (identified at the temperature T₀) and it varies with temperature. Knowing how the acoustic path Hₕₚₘ, is modified with temperature, it is possible to apply that modification to the canceller 11 by updating its coefficients. The canceller 11 then corresponds exactly to the acoustic path Hₕₚₘ at the new temperature. Maximum stabilization of the cell is once more ensured.

According to the invention, the updating of the coefficients of the canceller 11 is calculated as a function of the wave propagation time delay introduced by the change of temperature. For an initial temperature T₀ varying to a present temperature Tᵢ, the value of the time delay introduced by the temperature difference ΔT=Tᵢ−T₀ is given by the following equation: with

$$Δτ = {τ}_{i} - {τ}_{0} = \frac{d}{{( γ R )}^{1 / 2}} \frac{1}{{( {T}_{0} )}^{1 / 2}} ( \frac{1}{{( 1 + Δ T / {T}_{0} )}^{1 / 2}} - 1 )$$

γ=1.4

R=287 joules per kilogram-kelvin (J/kg·K) and

ΔT=Tᵢ−T₀=the temperature in kelvins.

The delay that needs to be introduced in the response of the stabilization filter is given in fractions of the sampling period by Δτₛ=fₛΔτ where fₛ represents the sampling frequency. The algorithm given below introduces this delay into the response of the filter in the frequency domain. The discrete Fourier transform of the initial stabilization filter is written as follows:

$${\tilde{W}}_{i} ( {f}_{k} ) = {\sum }_{n = 0}^{Wlen - 1} {W}_{i} ( n ) exp ( - 2 πj kn / Wlen ) , {f}_{k} = \frac{{kf}_{s}}{Wlen} , \\ k = 0 , 1 , … , Wlen - 1$$

where j=\sqrt{−1}. The discrete Fourier transform of the present stabilization filter is obtained by multiplying the delay term (complex terms):

\tilde{W}(fₖ)=\tilde{W}ᵢ(fₖ)exp(−2πjkΔτₛ/Wlen), k=0,1, . . . , Wlen−1

where Δτₛ represents the delay expressed as fractions of the sampling period. The coefficients of the present filter are obtained by the inverse Fourier transform:

$$W ( n ) = {\sum }_{k = 0}^{Wlen - 1} \tilde{W} ( {f}_{k} ) exp ( + 2 πj kn / Wlen ) , n = 0 , 1 , … , Wlen - 1$$

Only the real parts of the above-calculated coefficients are retained, since the non-zero imaginary parts are due to rounding errors.

FIG. 3 shows how temperature compensation can be implemented in a structure as shown in FIG. 1. The frequency response of the acoustic path Hₕₚₘ is subjected to frequency drift depending on temperature variation—the frequency spectrum is shifted towards higher frequencies when the temperature increases and towards lower frequencies when temperature decreases. That is why a filter 15 is added to the signal processor unit of the cell in order to correct the frequency shift. If x₁ is the signal input to the filter 15 and y₁ is the signal output by the filter 15, then the filter 15 leads to the relationship:

Y₁(f)=x₁(f+Δf)

where f is the frequency of the signal and Δf is the frequency shift of the signal. The quantity Δf is calculated as a function of temperature so as to compensate for the frequency shift generated by a temperature change.

FIG. 4 shows another way in which the invention may be applied. Reference 31 designates an auditorium. In the auditorium, there are a plurality of acoustic cells C1, C2, C3, C4, etc. In the application described herein, each cell comprises a microphone M1, a loudspeaker HP1 for the cell C1, and a microphone M2 and a loudspeaker HP2 for the cell C2. The cells C3 and C4 are respectively provided in the same way with microphones M3, M4 and with loudspeakers HP3, HP4, etc.

All of the cells C1, C2, C3, C4 are connected together via connections LL1, LL2, LL3, LL4 and an interconnection circuit 40.

FIG. 5 is a diagram of the structure of the cell C1. Naturally, the other cells C2, C3, C4 may have the same structure.

The loudspeaker HP1 plays back a sound that takes account of the sound picked up by the various microphones: the microphone M1 and also the other microphones M2, M3, M4 transiting via the various connections LL1, LL2, LL3, LL4. The sound picked up by the microphone M1 may also be transmitted to the other cells C2, C3, C4 over the connection LL1.

The various sounds from all of the microphones are added together by a matrixing circuit essentially constituted by an adder 50, each of the sounds being subjected to appropriate weighting processing by variable-gain amplifiers AP1, AP2, AP3, AP4. In addition, each of these sounds is delayed by delay units TP2, TP3, TP4 associated respectively with the microphones M2, M3, M4 so as to compensate for the acoustic propagation delays due to the respective distances between the cell C1 and the cells C2, C3, C4. It is also possible to apply reverberation processing by circuits RV2, RV3, RV4. After the above-mentioned processing, the sounds are applied to the loudspeaker HP1.

The cell C1 is fitted with an echo-canceller circuit 60 formed essentially by a filter FIR that involves a multitude of coefficients. At the input to this circuit 30, there is a replica of the signal applied to the input of the loudspeaker HP1. The echo signal then generated by the circuit 60 is subtracted from the signal delivered by the microphone M1 by means of a subtracter circuit 65.

Such a device suffers from quality degradation as a function of ambient temperature.

According to the invention, the various cells C1, C2, C3, C4 are provided with respective thermometer members T1, T2, T3, T4 that measure ambient temperature in order to act on the echo-canceller circuit 60.

Thus, each cell receives an indication of the temperature Tᵢ so as to correct the harmful influence of temperature changes relative to the temperature T₀ at which the initial adjustments were made.

The temperature correction acts on the coefficients so as to provide a delay Δτ relative to the time τ₀, at which the initial adjustment was performed, using a relationship of the following type as explained above:

$$Δτ = {τ}_{i} - {τ}_{0} = \frac{d}{{( γ R )}^{1 / 2}} \frac{1}{{( {T}_{0} )}^{1 / 2}} [ \frac{1}{{( 1 + Δ T / {T}_{0} )}^{1 / 2}} - 1 ]$$

with:

γ=1.4

R=287 J/kg·K)

ΔT=Tᵢ−T₀=the temperature in kelvins

τ₀ to the delay established during initial adjustment.

The delay introduced in this way serves to act on the direct acoustic path going from the loudspeaker of the cell in question to the microphone of the same cell.

1. An electroacoustic device for use in particular in a concert hall, the electroacoustic device including at least a soundwave pickup member and a soundwave playback member connected together by at least one processor circuit, the device being characterized in that wherein said processor circuit includes a compensation member for compensating the effect of instability due to temperature variation.

2. The device according to claim 1, wherein the compensation member is formed by a frequency filter whose tuning that depends on temperature.

3. The device according to claim 1, wherein the processor circuit comprises an echo-canceller filter applying a certain delay, wherein the processor circuit acts on the echo-canceller filter as a function of temperature.

4. The device according to claim 1, having a plurality of acoustic cells each formed by at least one sound pickup member, and at least one soundwave playback member and including an echo-canceller formed by a filter involving a multitude of coefficients, wherein the device is provided with a thermometer member for measuring ambient temperature in order to act on the multitude of coefficients as a function of ambient temperature.

5. The electroacoustic device according to claim 4, wherein said echo-canceller circuit receives replicas coming from a plurality of sound pickup members included in said device, which replicas are combined by a matrixing circuit.

6. The electroacoustic device according to claim 4, wherein the values of said coefficients are changed to provide a variation of delay Δτ relative to the time τ0 as determined on initial adjustment by means of a relationship of the following type:
$$Δτ = {τ}_{i} - {τ}_{0} = \frac{d}{{( γ R )}^{1 / 2}} \frac{1}{{( {T}_{0} )}^{1 / 2}} [ \frac{1}{{( 1 + Δ T / {T}_{0} )}^{1 / 2}} - 1 ]$$
with:
γ=1.4
R=287 J/kg·K)
ΔT=Tᵢ−T₀=the temperature in kelvins.
